(19) United States
(12) Patent Application Publication
(10) Pub. No.: US 2017/0287757 A1
(43) Pub. Date: Oct. 5, 2017

(54) DAMAGE MONITOR

(71) Applicants: Robert F. Kwasnick, Palo Alto, CA (US); Min Pei, Hillsboro, OR (US); Alan E. Lucero, Tempe, AZ (US)

(72) Inventors: Robert F. Kwasnick, Palo Alto, CA (US); Min Pei, Hillsboro, OR (US); Alan E. Lucero, Tempe, AZ (US)

(21) Appl. No.: 15/084,724

(22) Filed: Mar. 30, 2016

(51) Int. Cl. H01L 21/67; G01N 25/72

(52) U.S. Cl. CPC H01L 21/67288; G01N 25/72

(57) ABSTRACT

Devices and methods are shown that use sensors to detect physical characteristics of an IC circuit or other device over time. The physical characteristics and time data may be used to calculate a damage metric of the IC circuit or other device. The damage metric may be used to notify a user about a condition of the IC circuit or other device.

### BACKGROUND

Integrated circuits produce heat when operating. The temperature changes produced by integrated circuits (“IC”) can damage the solder joints located within the integrated circuit. Damage to solder joints can diminish the performance of the integrated circuit either partially or entirely.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is a cross-sectional view of one example of an IC package in accordance with some embodiments of the invention.

FIG. 2A is a schematic view of one example of a semiconductor device.

FIG. 2B is a schematic view of one example of a semiconductor device.

FIG. 3 is a block diagram of an electronic device incorporating a semiconductor device.

FIG. 4 is a block diagram of a method for monitoring the deterioration of a semiconductor device.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

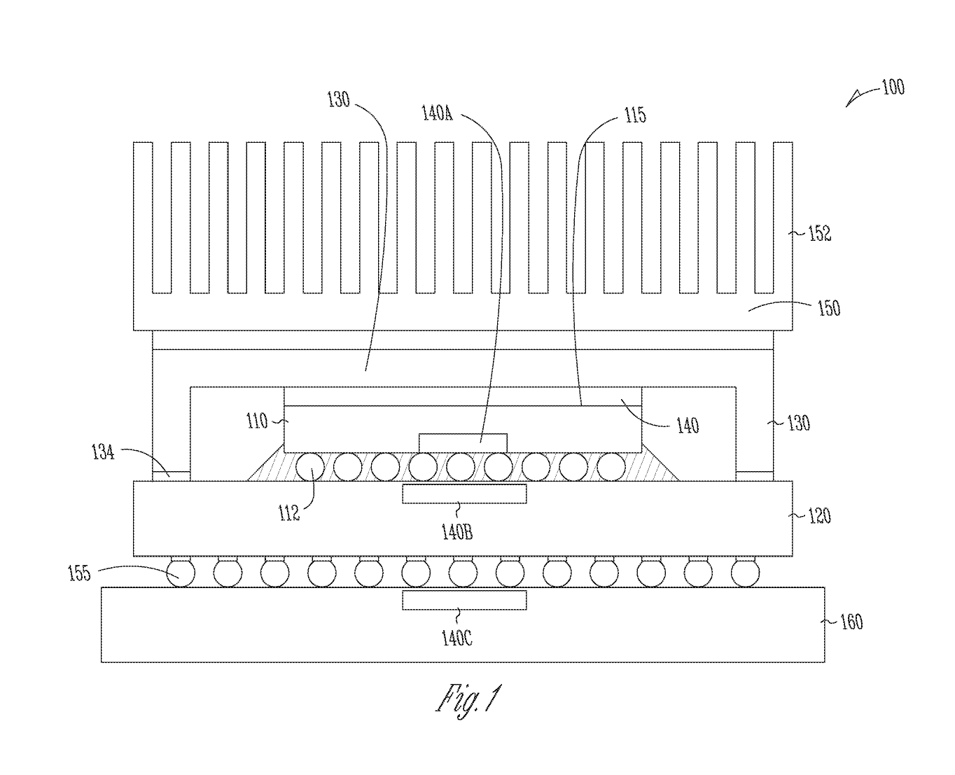

FIG. 1 shows a cross-sectional representation of an IC package 100. In embodiments where the IC die is a processor die, the IC package can be termed a processor assembly. IC package 100 includes a die 110 mounted in “flip-chip” orientation with its active side facing downward to couple with an upper surface of a substrate 120, through interconnections 112 such as solder balls or bumps. The substrate 120 also shows a number of second level interconnections 155 on its opposite surface for mating with additional packaging structures such as boards (not shown).

Die 110 generates its heat from structures, including wiring traces, located near its active side; however, a significant portion of the heat is dissipated through its back side 115. Heat that is concentrated within the die 110 is dissipated to a large surface that is in contact with the die 110 in the form of an integrated heat spreader 130. A thermal interface material 140 is often provided between the die 110 and integrated heat spreader 130. In one embodiment, to further dissipate heat from the integrated heat spreader 130, a heat sink 150 optionally having fins 152 is coupled to the integrated heat spreader 130 through a second thermal interface material 154.

The temperature change that results from operation of the die 110 can negatively affect performance of the die 110 and other surrounding electronic devices (e.g., random access memory, hard disk drives, solid disk drives, motherboards, graphics cards, etc.). In an example, the die 110 generates heat as it operates (e.g., in a powered state). In another example, the temperature of the die 110 will increase as workloads increase, and conversely, the temperature of the die 110 will decrease as workloads decrease. As the temperature changes within the die 110, the various parts of the die 110 expand and contract, depending upon the coefficient of thermal expansion for the various materials that comprise the parts of the die 110. Similarly, the temperature fluctuations caused by the operation of the die 110 can also result in damage to the interconnections 112 or the second level interconnections 155. The expansion and contraction of the various parts of the die 110 introduces stresses and strains within those parts and where those parts are coupled together, ultimately resulting in fatigue and creep, which can then cause failure.

Fatigue is substantially a thermo-mechanical process of failure. Creep is substantially a mechanical process of failure, but can also be dependent on temperature. Fatigue occurs when a stress or strain is applied to an object in a cyclical manner. Creep is a time-dependent deformation of an object where stress and/or temperature have a substantial impact on the amount of creep experienced by the object. However, temperature is a factor in both the fatigue and creep processes. In an example, the accuracy of a measurement of the amount of creep an object experiences is improved when time and temperature data are recorded simultaneously. In one example, it is difficult or impossible to predict creep without a measured time component. In another example, the accuracy of a prediction of failure of a component, such as die 110, is improved when time, temperature, and humidity data are recorded simultaneously. Accurately tracking creep and fatigue can improve system performance, decrease service outages, improve product design by verifying simulations and theoretical models, and improve the predictions of failure for components, among other things.

In an example, an electrical component can be placed in physical proximity of the substrate 120 and then soldered to the substrate 120, thus physically and electrically coupling the electrical component and the substrate 120. As the electrical component is operated, it is subjected to a wide range of temperature fluctuations. The electrical component, the solder, and the substrate 120 each will have differing geometries and their respective materials will have differing coefficients of thermal expansion. The differing geometries and mechanical properties of the coupled parts introduces stresses and strains into the parts. The repeated cycling of the electrical component results in fatigue and potentially failure of the physical and electrical coupling of the parts. The failure of the physical and electrical coupling of the parts can lead to failure of the device incorporating those parts (e.g., a decrease in the utility of the device). In an example, solder joints can comprise soft metals and can be particularly susceptible to thermo-mechanical damage due to metal fatigue and creep, possibly causing the product to fail due to either an electrical open or short at the solder joint.

The IC package 100 can have one or more sensors 140A-C. The one or more sensors 140A-C can be located proximate to the die 110. In an example, the one or more sensors 140A-C are proximate to the die 110 such that the one or more sensors 140A-C are able to sense data that is relevant to the operation of the die 110 or its surroundings. In one example, the sensor 140A can be fabricated into the die 110 such that it is an internal component within the die 110. In another example, the sensor 140B can be located on the package of an integrated circuit (e.g., located on the substrate 120). In yet another example, the sensor 140C can be located on a printed circuit board (e.g., a motherboard 160). In still yet another example, the one or more sensors 140A-C can be located within the chassis (i.e., the case) of a computer or an electronic device. Alternatively or additionally, the one or more sensors 140A-C can be located remote from the die 110. Other locations of the one or more sensors 140A-C are also contemplated and within the scope of the invention.

The one or more sensors 140A-C can measure analog physical characteristics (e.g., temperature, humidity, electrical resistance, electrical capacitance, electrical voltage, or electrical current) of electrical parts and/or their environmental surroundings. For example, the electrical resistance of sensor 140A can vary with changes in temperature of the die 110. In one example, resistance of a component such as a diode is measured, and can be correlated to a temperature. Likewise, in one example other electrical components may be used to directly measure an electrical characteristic that varies with a change in humidity.

In one example, the sensor 140B can sense the temperature of the substrate 120. In yet another example, the one or more sensors 140A-C can sense the humidity of the environment surrounding the IC package 100 (e.g., the humidity within the case or chassis of an electrical device, or within the room where the electronic device is located). The one or more sensors 140A-C are provided as examples. It is contemplated that there could be just a single sensor, more than one sensor, or more than three sensors.

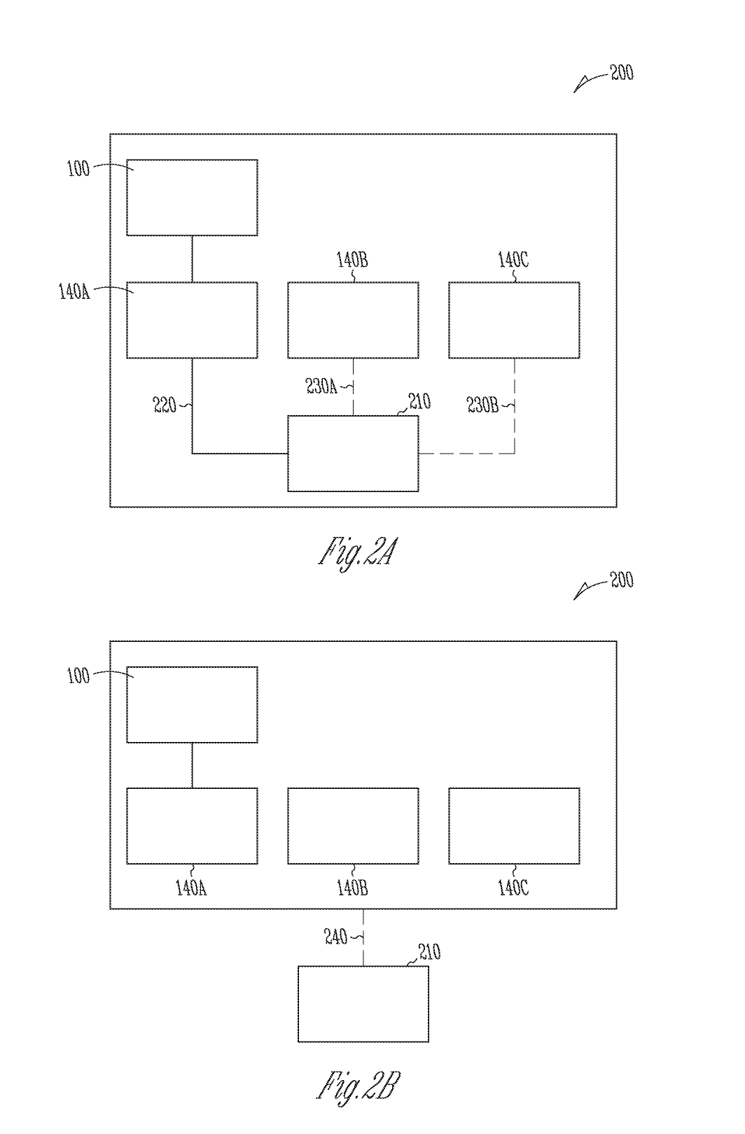

FIG. 2A is a schematic view of one example of a semiconductor device 200. In one example, the semiconductor device 200 can have the IC package 100 (including die 110), one or more sensors 140A-C, and a damage metric module 210.

As discussed above with reference to FIG. 1, the one or more sensors 140A-C can be located proximate to the die 110 (e.g., located as an internal component of the die 110, as part of the package of the die 110, within a computer case or chassis housing the die 110, or in the same room as the die 110). The one or more sensors 140A-C can be in communication with the damage metric module 210. The communication between the one or more sensors 140A-C and the damage metric module 210 can be either wired or wireless forms of communication.

Specifically, the communication between the one or more sensors 140A-C and the damage metric module 210 can be through electrical communication through one or more conductors 220. Alternatively or additionally, the communication between the one or more sensors 140A-C and the damage metric module 210 can be through wireless communication such as wireless link 230A-B. The wireless link 230A-B can facilitate communication between the one or more sensors 140A-C and the damage metric module 210 by transmitting electromagnetic energy (e.g., radio waves), representative of the sensed physical characteristics of, and the environment surrounding, the die 110 through a medium (e.g., air). The wireless link 230A-C can utilize standardized forms of wireless communication such as the IEEE 802.11 (Wi-Fi) standards, Bluetooth Core Specification versions 1.0-4.2, or cellular networks (e.g., GSM, CDMA, GPRS, EDGE, AMPS, and/or LTE), but is not so limited.

In one example, the damage metric module 210 is configured to process multiple data points of time and temperature during operation of the die 110. In another example, the damage metric module 210 is configured to process multiple data points of time and humidity during operation of the die 110. In still yet another example, the damage metric module 210 is configured to process multiple data points of time, temperature, and humidity during operation of the die 110. The damage metric module 210 can sample the information provided by the one or more sensors 140A-C either continuously or intermittently.

In an example, the damage metric module 210 processes multiple data points of time and one or more physical characteristics (e.g., temperature and/or humidity) of the die 110 and/or the environment surrounding the die 110. The damage metric module 210 receives data, either analog or digital, from the one or more sensors 140A-C. The damage metric module 210 can be configured to convert the sensed analog physical characteristics of the one or more sensors 140A-C into a digital representation that correlates with the sensed analog physical characteristic. Stated another way, in an example, the sensor 140A can be a thermocouple that indicates temperature by a specific voltage difference between two dissimilar metals that are coupled with one another. The damage metric module 210 is capable of processing the sensed voltage output by the sensor 140A and converting it into a digital (e.g., binary) representation that is equivalent to the sensed voltage output (e.g., sensor 140A outputs a voltage of 1.5V, the damage metric module will convert that data into an equivalent digital representation of the temperature).

In an example, the damage metric module 210 processes the multiple data points by manipulating the data and inputting the data into a pre-defined, product-specific, damage metric algorithm. The algorithm determines the probability that damage (e.g., mechanical and thermo-mechanical wear processes) has occurred to the semiconductor device 200. The result of the processing done by the damage metric module 210 is a damage metric.

In one example, the damage metric module is at least partially hardware based. For example, in one example, the damage metric module is a damage metric circuit. In one example, the damage metric module 210 can be either partially or entirely software based (i.e., the functionality provided by the damage metric module 210 can be provided by a software implementation of the functionality described herein). In one example, the damage metric module 210 is a combination of hardware based and software based. In yet another example, the damage metric is indicative of the amount of inelastic strain the semiconductor device 200 has experienced. The damage metric can be used to determine when to replace or provide maintenance to the semiconductor device 200 since the damage metric reflects the probability that the semiconductor device 200 has experienced damage that would adversely affect performance of the semiconductor device 200.

In one example, the damage metric module is configured to communicate to a user a damage condition of the IC package. For example, a message that the IC package has a percentage of life remaining before replacement is recommended, or a message that a certain time remains before replacement is recommended, or a message that the IC package should be replaced.

In an example, the damage metric module is configured to maintain one or more damage metrics. The one or more damage metrics can be associated with one or more parts (e.g., the die 110, the substrate 120, or the motherboard 160). In another example, the maintaining of the one or more damage metrics involves storing the one or more damage metrics in local or remote memory (either volatile or non-volatile) such that the damage metric can be tracked over the entire life of the one or more parts that are each associated with the respective damage metric.

Alternatively or additionally, the one or more sensors 140A-C can sense the temperature of a first component, and the damage metric module 210 can transpose the sensed temperature of the first component to a determined temperature of a second component. Stated another way, the damage metric module 210 can be configured to measure the temperature of a first component and extrapolate the temperature of a second component through mathematical models or simulations (e.g., the Norris-Landzberg equation or cumulative inelastic strain). FIG. 2B is a schematic view of one example of a semiconductor device 200. In an example, the damage metric module 210 can be located remote from the die 110 and the one or more sensors 140A-C and the die 110. The data sensed by the one or more sensors 140A-C can be stored locally in either volatile or non-volatile memory. The sensed data can then be transmitted to the damage metric module 210 that can be located within the same electronic device, the same building, in a different city, or in a different country as the one or more sensors 140A-C and the die 110. The damage metric module 210 then processes the one or more data points and produces a damage metric, as previously described herein. Communication link 240 can be configured to provide the same functionality as conductors 220 and wireless link 230A-B, as previously described herein. Communication link 240 can facilitate the communication between the one or more sensors 140A-C and the remotely-located damage metric module (e.g., through the internet).

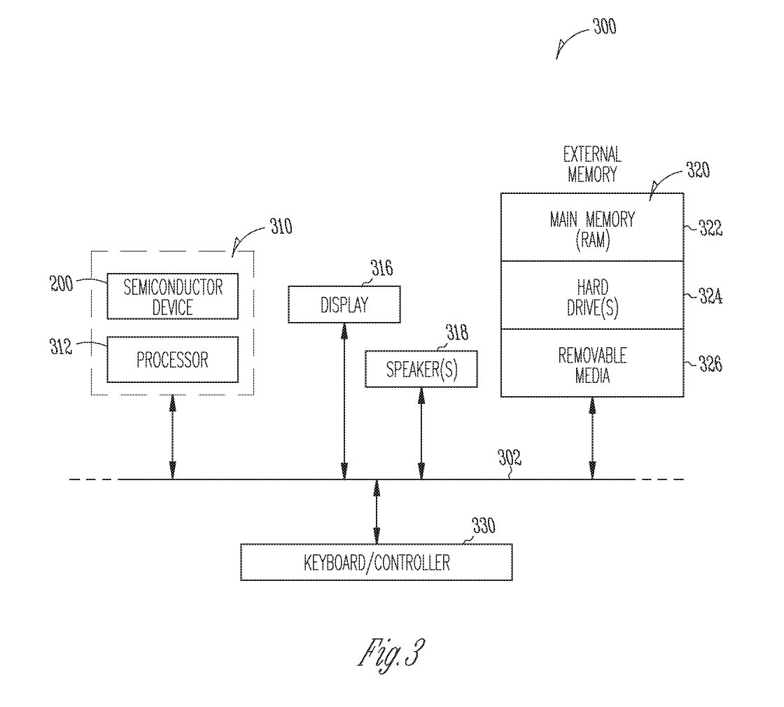

An example of an electronic device using semiconductor chip assemblies and solders as described in the present disclosure is included to show an example of a higher level device application for the present invention. FIG. 3 is a block diagram of a system 300 incorporating at least one semiconductor device and/or method in accordance with at least one embodiment of the invention. System 300 is merely one example of an electronic system in which embodiments of the present invention can be used. It is contemplated that the present subject matter will be applicable to other devices and systems. Examples of systems 300 include, but are not limited to personal computers, portable electronic devices (e.g., mobile telephones, game devices, MP3 or other digital music players, tablet computers, laptops, etc.), televisions, and gaming consoles. In this example, system 300 comprises a data processing system that includes a system bus 302 to couple the various components of the system. System bus 302 provides communications links among the various components of the system 300 and can be implemented as a single bus, as a combination of busses, or in any other suitable manner.

An electronic assembly 310 is coupled to system bus 302. The electronic assembly 310 can include any circuit or combination of circuits (e.g., semiconductor device 200). In one embodiment, the electronic assembly 310 includes a processor 312 (of which the die 110 can be a component) which can be of any type. As used herein, “processor” means any type of computational circuit, such as but not limited to a microprocessor, a microcontroller, a complex instruction set computing (CISC) microprocessor, a reduced instruction set computing (RISC) microprocessor, a very long instruction word (VLIW) microprocessor, a graphics processor, a digital signal processor (DSP), multiple core processor, or any other type of processor or processing circuit.

Other types of circuits that can be included in electronic assembly 310 are a custom circuit, an application-specific integrated circuit (ASIC), or the like, such as, for example, one or more circuits (such as a damage metric module 210) for use in electronic devices like personal computers, portable electronic devices, televisions or gaming consoles. The IC can perform any other type of function.

The system 300 can also include an external memory 320, which in turn can include one or more memory elements suitable to the particular application (e.g., storing a damage metric or physical characteristic data), such as a main memory 322 in the form of random access memory (RAM), one or more hard drives 324, and/or one or more drives that handle removable media 326 such as compact disks (CD), flash memory cards, digital video disk (DVD), and the like.

The system 300 can also include a display device 316, one or more speakers 318, and a keyboard and/or controller 330, which can include a mouse, trackball, touch screen, voice-recognition device, or any other device that permits a system user to input information into and receive information from the system 300. In an example, the temperature of the components of the system 300 can be measured and recorded (or modeled through mathematical equations) and a damage metric can be determined for those components.

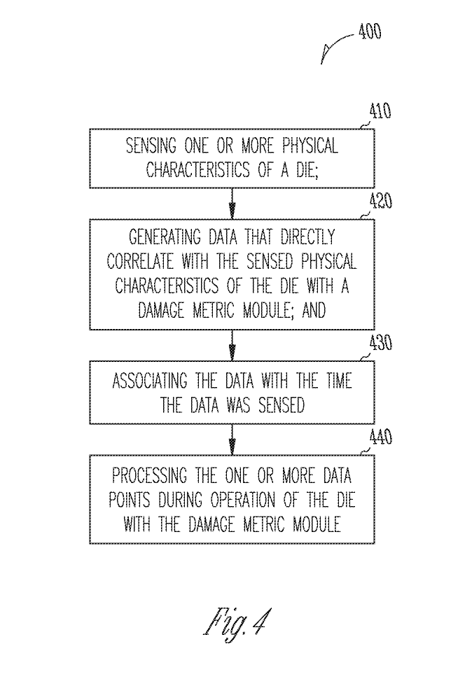

FIG. 4 is a block diagram of a method 400 for monitoring the deterioration of a semiconductor device. In one example, the step 410 involves sensing one or more physical characteristics of a die 110. The step 420 involves generating data that directly correlate with the sensed physical characteristics of the die 110 with a damage metric module 210. The step 430 involves associating the data with the time the data was sensed. The step 440 involves processing the one or more data points during operation of the die 210 with the damage metric module 210.

In another example, the method 400 includes sensing one or more physical characteristics of the atmosphere proximate to the die 110, generating data that directly correlate with the sensed physical characteristics of the atmosphere proximate to the die 110, and processing the data during operation of the die 110 with a damage metric module 210. In yet another example, the method 400 includes notifying a user that the amount of damage experienced by the integrated circuit (e.g., the die 110) exceeded a predefined threshold. In still yet another example, the method 400 includes notifying a user that the probability that the integrated circuit (e.g., the die 110) has experienced damage has exceeded a predefined threshold. Alternatively or additionally, the method 400 can include notifying a user that a damage metric for a part has exceeded a predefined threshold for that part. Further, the method 400 can also include that the processing of the data further includes converting a sensed analog physical characteristic to digital data that corresponds to the sensed analog physical characteristic. In an example, the predefined threshold can be determined through laboratory studies that are conducted on many products during the design process.

In still yet another example, method 400 can include that the processing of the one or more data points occurs while the die 110 is in an unpowered state. The processing of the one or more data points while the die 110 is in an unpowered state improves the accuracy of the damage metric that is reflective of the amount of damage the die 110 (or other components such as substrate 120) has experienced. Processing in an unpowered state improves the accuracy of the damage metric because data is collected over the entire life of die 110 (or other parts) as opposed to when the die 110 is only in a powered state. In an example, the semiconductor device 200 can be in a room without climate control. If the die 110 within the semiconductor device 200 were in an unpowered state, and the damage metric module 210 was not processing the sensed data provided by the one or more sensors 140A-C, the damage metric module 210 would be unaware of the climatological variations in the room when the die 110 is in an unpowered state. Thus, the damage metric module would also be unaware of the resulting fatigue and creep experienced by the semiconductor device 200 while in the unpowered state, thereby decreasing accuracy of the damage metric.

Stated another way, the accuracy of a damage metric can be improved if data is collected when the die 110 is in an unpowered state. In one example, an assumption is made that when the die 110 is switched from a powered to an unpowered state, the die 110 will reach the ambient temperature of its surroundings. The damage metric module 210 will use the ambient temperature and the duration that the die 110 was in an unpowered state when calculating the damage metric, thereby improving the accuracy of the damage metric. In another example, the ambient temperature can be measured and recorded while the die 110 is in an unpowered state. The recorded data can then be used by the damage metric module 210 in calculating the damage metric, thereby improving the accuracy of the damage metric. In other words, the damage metric module 210 can be configured to remain in a powered state and process multiple data points while the die 110 is in an unpowered state (e.g., when the die 110 is not operating), thereby improving the accuracy of the damage metric.

### VARIOUS NOTES & EXAMPLES

Example 1 can include or use a semiconductor device comprising a die, one or more sensors proximate to the die, and a damage metric module in communication with the one or more sensors, wherein the damage metric module is configured to process multiple data points of time and temperature during operation of the die.

Example 2 can include or use, or can optionally be combined with the subject matter of Example 1, to optionally include or use a damage metric module configured for the processing of multiple data points includes manipulating the time and temperature data to yield a damage metric, the damage metric indicative of the amount of thermo-mechanical wear the semiconductor device has experienced.

Example 3 can include or use, or can optionally be combined with the subject matter of one or any combination of Examples 1 or 2 to optionally include or use a damage metric module that is further configured to process multiple data points of humidity during operation of the die.

Example 4 can include or use, or can optionally be combined with the subject matter of one or any combination of Examples 1 through 3 to optionally include or use a damage metric module configured to process multiple data points while the die is in an unpowered state.

Example 5 can include, or can optionally be combined with the subject matter of one or any combination of Examples 1 through 4 to optionally include or use a damage metric module that samples the multiple data points continuously.

Example 6 can include, or can optionally be combined with the subject matter of one or any combination of Examples 1 through 5 to optionally include or use a damage metric module that samples the multiple data points intermittently.

Example 7 can include, or can optionally be combined with the subject matter of one or any combination of Examples 1 through 6 to optionally include or use a damage metric module that is located remote from the die and the one or more sensors.

Example 8 can include, or can optionally be combined with the subject matter of one or any combination of Examples 1 through 7 to optionally include or use one or more sensors that are fabricated into the die.

Example 9 can include, or can optionally be combined with the subject matter of one or any combination of Examples 1 through 8 to optionally include or use one or more sensors that measure the resistance of a diode.

Example 10 can include, or can optionally be combined with the subject matter of one or any combination of Examples 1 through 9 to optionally include or use one or more sensors that are located on a package of an integrated circuit.

Example 11 can include, or can optionally be combined with the subject matter of one or any combination of Examples 1 through 10 to optionally include or use one or more sensors that are located on a printed circuit board.

Example 12 can include or use a semiconductor device comprising a die, one or more sensors proximate to the die, and a damage metric module in communication with the one or more sensors, wherein the damage metric module is configured to process multiple data points of time and humidity during operation of the die.

Example 13 can include or use, or can optionally be combined with the subject matter of Example 12, to optionally include or use a damage metric module configured for the processing of multiple data points includes manipulating the time and humidity data to yield a damage metric, the damage metric indicative of the amount of thermo-mechanical wear the semiconductor device has experienced.

Example 14 can include or use, or can optionally be combined with the subject matter of one or any combination of Examples 12 or 13 to optionally include or use a damage metric module configured for processing of multiple data points occurs while the die is in an unpowered state.

Example 15 can include or use, or can optionally be combined with the subject matter of one or any combination of Examples 12 through 14 to optionally include or use a damage metric module that samples the multiple data points continuously.

Example 16 can include or use, or can optionally be combined with the subject matter of one or any combination of Examples 12 through 15 to optionally include or use a damage metric module that samples the multiple data points intermittently.

Example 17 can include or use, or can optionally be combined with the subject matter of one or any combination of Examples 12 through 16 to optionally include or use a damage metric module that is located remote from the die and the one or more sensors.

Example 18 can include or use a method for monitoring the deterioration of a semiconductor device, comprising sensing one or more physical characteristics of a die, generating data that directly correlate with the sensed physical characteristics of the die with a damage metric module, associating the data with the time the data was sensed, and processing the one or more data points during operation of the die with the damage metric module.

Example 19 can include or use, or can optionally be combined with the subject matter of Example 18, to optionally include or use sensing one or more physical characteristics of the atmosphere proximate to the die, generating data that directly correlate with the sensed physical characteristics of the atmosphere proximate to the die, and processing the data during operation of the die with a damage metric module.

Example 20 can include or use, or can optionally be combined with the subject matter of one or any combination of Examples 18 or 19 to optionally include or use notifying a user that the amount of thermo-mechanical damage experienced by the integrated circuit exceeded a predefined threshold.

Example 21 can include or use, or can optionally be combined with the subject matter of one or any combination of Examples 18 through 20 to optionally include or use processing of the one or more data points that occurs while the die is in an unpowered state.

Each of these non-limiting examples can stand on its own, or can be combined in various permutations or combinations with one or more of the other examples.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

The claimed invention is:

1. A semiconductor device, comprising:
a die;
one or more sensors proximate to the die; and
a damage metric module in communication with the one or more sensors, wherein the damage metric module is configured to process multiple data points of time and temperature during operation of the die.

2. The semiconductor device of claim 1, wherein the damage metric module processing of multiple data points includes manipulating the time and temperature data to yield a damage metric, the damage metric indicative of the amount of thermo-mechanical wear the semiconductor device has experienced.

3. The semiconductor device of claim 1, wherein the damage metric module is further configured to process multiple data points of humidity during operation of the die.

4. The semiconductor device of claim 1, wherein the damage metric module is further configured to process multiple data points while the die is in an unpowered state.

5. The semiconductor device of claim 1, wherein the damage metric module samples the multiple data points continuously.

6. The semiconductor device of claim 1, wherein the damage metric module samples the multiple data points intermittently.

7. The semiconductor device of claim 1, wherein the damage metric module is located remote from the die and the one or more sensors.

8. The semiconductor device of claim 1, wherein the one or more sensors are fabricated into the die.

9. The semiconductor device of claim 1, wherein the one or more sensors measure the resistance of a diode.

10. The semiconductor device of claim 1, wherein the one or more sensors are located on a package of an integrated circuit.

11. The semiconductor device of claim 1, wherein the one or more sensors are located on a printed circuit board.

12. A semiconductor device, comprising:
a die;
one or more sensors proximate to the die; and
a damage metric module in communication with the one or more sensors, wherein the damage metric module is configured to process multiple data points of time and humidity during operation of the die.

13. The semiconductor device of claim 12, wherein the damage metric module processing of multiple data points includes manipulating the time and humidity data to yield a damage metric, the damage metric indicative of the amount of thermo-mechanical wear the semiconductor device has experienced.

14. The semiconductor device of claim 12, wherein the damage metric module processing of multiple data points occurs while the die is in an unpowered state.

15. The semiconductor device of claim 12, wherein the damage metric module samples the multiple data points continuously.

16. The semiconductor device of claim 12, wherein the damage metric module samples the multiple data points intermittently.

17. The semiconductor device of claim 12, wherein the damage metric module is located remote from the die and the one or more sensors.

18. A method for monitoring the deterioration of a semiconductor device, comprising:
sensing one or more physical characteristics of a die;
generating data that directly correlate with the sensed physical characteristics of the die with a damage metric module;
associating the data with the time the data was sensed; and
processing the one or more data points during operation of the die with the damage metric module.

19. The method of claim 18, further comprising sensing one or more physical characteristics of the atmosphere proximate to the die, generating data that directly correlate with the sensed physical characteristics of the atmosphere proximate to the die, and processing the data during operation of the die with a damage metric module.

20. The method of claim 18, further comprising notifying a user that the amount of thermo-mechanical damage experienced by the integrated circuit exceeded a predefined threshold.

21. The method of claim 18, wherein the processing of the one or more data points occurs while the die is in an unpowered state.
